(19) United States
(12) Patent Application Publication
(10) Pub. No.: US 2006/0197615 A1
(43) Pub. Date: Sep. 7, 2006

(54) Ultra low power oscillator

(75) Inventors: Ja-nam Ku, Yongin-si (KR); Chung-woul Kim, Andong-si (KR); Young-hoon Min, Anyang-si (KR); Il-jong Song, Suwon-si (KR); Dong-hyun Lee, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/341,607

(22) Filed: Jan. 30, 2006

(30) Foreign Application Priority Data
Feb. 22, 2005 (KR) 2005-0014643

(51) Int. Cl. H03K 3/03

(52) U.S. Cl. 331/57

(57) ABSTRACT

An ultra low power oscillator includes a current supply unit converting current supplied from an external bias power source into first and second low currents of predetermined amounts, and an oscillation unit oscillating and creating a predetermined frequency signal if the first and second low currents are supplied from the current supply unit. The oscillation unit includes a plurality of inverters connected in series, and the current supply unit includes a current limit circuit composed of NMOS and PMOS transistors connected to the respective inverters. The current flowing when the transistors in the respective inverters are simultaneously turned on is limited, and thus the power consumption can be reduced.

This application claims benefit under 35 U.S.C. § 119 from Korean Patent Application No. 2005-14643 filed on Feb. 22, 2005 in the Korean Intellectual Property Office, the disclosure of which is incorporated herein by reference.

### BACKGROUND OF THE INVENTION

1. Field of the Invention

The present invention relates to an ultra low power oscillator, and more particularly, to an ultra low power oscillator that supplies a low current using a current limit circuit to reduce power consumption.

2. Description of the Related Art

An oscillator is a device that generates an oscillating frequency signal of a predetermined level for use in a semiconductor chip. Generally, the oscillator can be implemented using a plurality of inverters.

FIG. 1 is a circuit diagram illustrating the construction of a conventional oscillator. Referring to FIG. 1, the conventional oscillator includes an oscillation unit 10 composed of a plurality of inverters 11, 12 and 13, and an output buffering unit 20 which buffers and outputs a signal from the oscillation unit 10. The output buffering unit 20 is also composed of a plurality of inverters. Each inverter includes a PMOS transistor and an NMOS transistor.

An external control signal is input to gate terminals ‘a’ of respective transistors MPO and MNO of a first inverter 11. If the external control signal is a low level signal, the transistor MNO is turned off and the transistor MPO is turned on. Thus, an output signal of the first inverter 11 becomes a high level signal by means of a bias power source Vdd connected to a drain terminal of the transistor MPO. Also, since an input signal of the second inverter 12 becomes a high level signal, a transistor MN1 is turned on and a transistor MP1 is turned off. Thus, an output signal of the second inverter 12 becomes a low level signal by means of a bias power source Vss connected to a drain terminal of the transistor MN1. In this way, the signal first input to the node ‘a’ is continuously inverted.

An output terminal of the oscillation unit 10 is connected with an input node. In this case, the output signal is again input to the node ‘a’ so that oscillation is carried out to output a predetermined frequency signal. The frequency of the signal output from the oscillation unit 10 is determined by a capacitor C0 and resistors R0 and R1 connected between the output node and the input node. Meanwhile, each inverter of the output buffering unit 20 buffers the signal output from the oscillation unit 10 and outputs the buffered signal to the outside. An oscillator of the above construction is referred to as an RC ring oscillator.

As described above, each inverter is composed of NMOS and PMOS transistors. In this case, a point of time when the NMOS and PMOS transistors are simultaneously turned on occurs during switching of the input signal. In the conventional oscillator, since the bias power sources Vdd and Vss are directly connected with their respective inverters, large current flows. Accordingly, power consumption greatly increases, and thus the conventional oscillator cannot be used for an ultra low power system that requires the whole current consumption within the range of several μA. Also, in the conventional oscillator, it is difficult to design output clock signals with waveforms symmetrical to each other based on a center level.

### SUMMARY OF THE INVENTION

The present invention has been developed in order to solve the above drawbacks and other problems not described above associated with the conventional arrangement. Also, the present invention is not required to overcome the disadvantages described above, and an illustrative, non-limiting embodiment of the present invention may not overcome any of the problems described above.

The present invention provides an ultra low power oscillator that can reduce power consumption by limiting current supplied to respective inverters using a current limit circuit.

The present invention also provides an ultra low power oscillator in which an output signal has a symmetric waveform about a center level.

According to an aspect of the present invention, there is provided an ultra low power oscillator, according to the present invention, which includes a current supply unit converting current supplied from an external bias power source into first and second low currents of predetermined amounts, and an oscillation unit oscillating and creating a predetermined frequency signal if the first and second low currents are supplied from the current supply unit.

The oscillation unit may include a plurality of inverters connected in series.

The oscillation unit may be constructed in the form of a ring, of which the output and input terminals are connected to each other by a feedback circuit.

The oscillation unit may further include a transistor switch that is connected to the feedback circuit to control oscillation.

The ultra low power oscillator may further comprise an output buffering unit buffering output signals of the oscillation unit and outputting the buffered signals.

Each inverter may include a first PMOS transistor having a source terminal to which the first low current is applied, and a first NMOS transistor having a source terminal to which the second low current is applied.

The current supply unit may include a current mirror circuit detecting first and second currents from the bias power source, and a current limit circuit converting the first and second currents into the first and second low currents and supplying the converted currents to the oscillation unit.

The current limit circuit may further include a second PMOS transistor having a drain terminal connected to the source terminal of the first PMOS transistor, and a second NMOS transistor having a drain terminal connected to the source terminal of the first NMOS transistor.

The second PMOS transistor has a current transfer characteristic twice greater than that of the second NMOS transistor.

### BRIEF DESCRIPTION OF THE DRAWINGS

The above and/or other aspects of the present invention will be more apparent by describing exemplary embodiments of the present invention with reference to the accompanying drawings, in which:

FIG. 1 is a circuit diagram illustrating the construction of a conventional ring oscillator;

FIG. 2 is a block diagram illustrating the construction of an ultra low power oscillator according to an exemplary embodiment of the present invention;

FIG. 3 is a circuit diagram of an ultra low power oscillator of FIG. 2;

FIG. 4 is a circuit diagram of a current mirror circuit used in the ultra low power oscillator of FIG. 2; and

FIGS. 5 to 7 are graphs illustrating experimental simulation results of the ultra low power oscillator of FIG. 2.

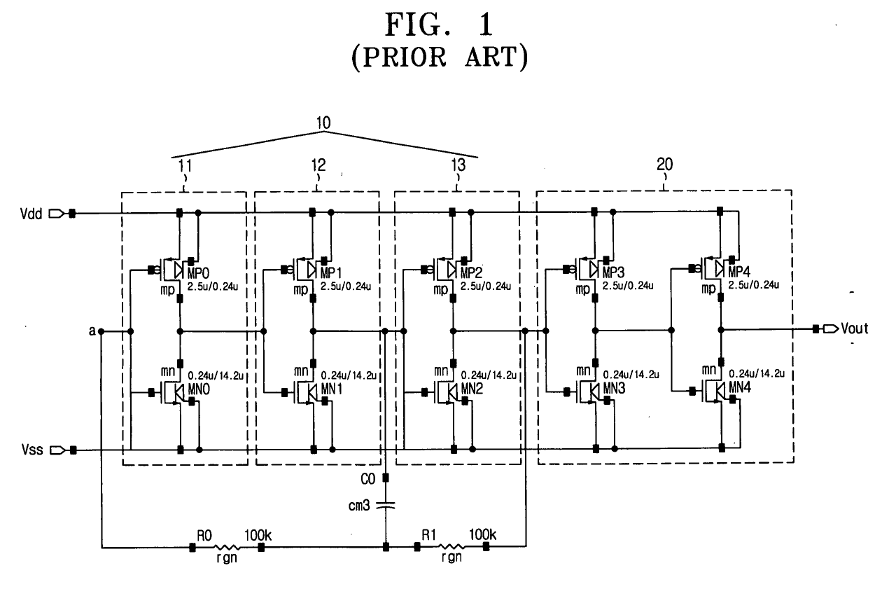

### DETAILED DESCRIPTION OF EXEMPLARY EMBODIMENTS

Certain exemplary embodiments of the present invention will be described in greater detail with reference to the accompanying drawings.

In the following description, same drawing reference numerals are used for the same elements even in different drawings. The matters defined in the description such as a detailed construction and elements are provided to assist in a comprehensive understanding of the invention. Thus, it is apparent that the present invention can be carried out without those defined matters. Also, well-known functions or constructions are not described in detail since they would obscure the invention with unnecessary detail.

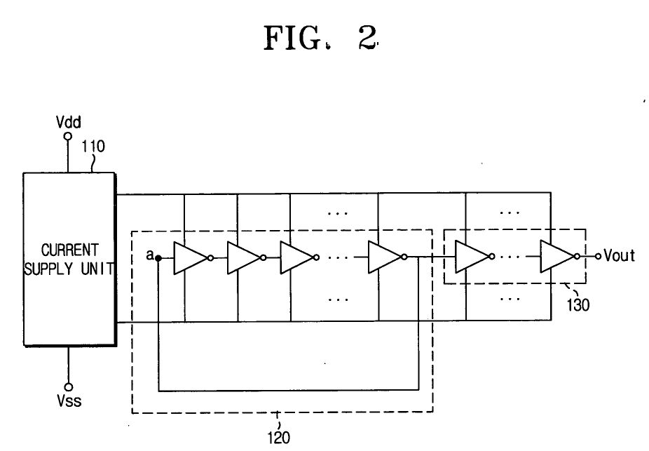

FIG. 2 is a block diagram illustrating the construction of an ultra low power oscillator according to an exemplary embodiment of the present invention. Referring to FIG. 2, the ultra low power oscillator according to the embodiment of the present invention includes a current supply unit 110, an oscillation unit 120 and an output buffering unit 130.

The current supply unit 110 converts currents from external bias power sources Vdd and Vss into first and second low currents, and supplies the first and second low currents to the oscillation unit 120.

The oscillation unit 120 is biased by the first and second low currents supplied from the current supply unit 110 so as to output a predetermined oscillating frequency signal depending on an external control signal. To this end, the oscillation unit 120 includes a plurality of inverters to which the first and second low currents are respectively applied. As described above, the oscillation unit 120 may have a ring shape in which its output terminal is connected to its input node.

The output buffering unit 130 buffers the frequency signal output from the oscillation unit 120 and outputs the buffered signal. The output buffering unit 130 is composed of at least one inverter.

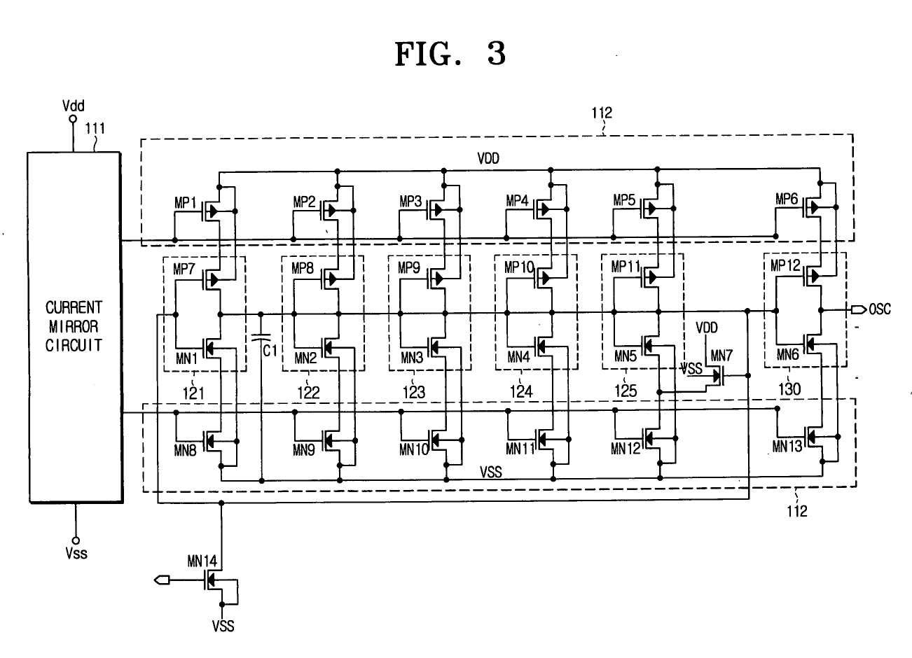

FIG. 3 is a circuit diagram illustrating an example of the ultra low power oscillator of FIG. 2. Referring to FIG. 3, the current supply unit 110 includes a current mirror circuit 111 and a current limit circuit 112. Also, the oscillation unit 120 is composed of five inverters 121 to 125, and the output buffering unit 130 is composed of one inverter. The number of inverters in the oscillation unit 120 and in the output buffering unit 130 may differ according to the exemplary embodiments of the present invention.

Each of the inverters 121 to 125 and 130 is composed of NMOS and PMOS transistors. A drain terminal of the NMOS transistor is connected with a source terminal of the PMOS transistor. An external control signal is input to each gate terminal of the NMOS and PMOS transistors constituting the first inverter 121. An output terminal of the fifth inverter 125 is connected to an input terminal of the first inverter 121 by a feedback circuit to form a ring shape.

The current mirror circuit 111 serves to detect first and second currents of predetermined amounts from the external bias power sources Vdd and Vss.

The current limit circuit 112 converts the first and second currents detected from the current mirror circuit 111 into first and second low currents so as to supply them to the respective inverters 121 to 125 and 130.

To this end, the current limit circuit 112 includes a plurality of NMOS and PMOS transistors connected to the respective inverters 121 to 125 and 130. Each drain terminal of the PMOS transistors in the current limit circuit 112 is connected with each source terminal of the PMOS transistors constituting the respective inverters 121 to 125 and 130. Also, each drain terminal of the NMOS transistors in the current limit circuit 112 is connected with each source terminal of the NMOS transistors constituting the respective inverters 121 to 125 and 130.

On the other hand, a drain terminal of a transistor switch MN14 is connected to the feedback circuit that connects an output terminal of the fifth inverter 125 with an input terminal of the first inverter 121 in the oscillation unit 120. A source terminal of the transistor switch MN14 is connected to the bias power source Vss, and the external control signal is input to a gate terminal of the transistor switch MN14. Thus, if the transistor switch MN14 is turned on, the bias power source Vss is applied to the input terminal of the first inverter 121 to fix the input signal. For this reason, oscillation is not performed. By contrast, if the transistor switch MN14 is turned off, the feedback circuit is normally connected to perform oscillation.

A capacitor C1 having a predetermined capacitance is connected between the output terminal of the first inverter 121 and the feedback circuit. Also, a transistor MN7 is connected to a transistor MN5 of the fifth inverter 125. Thus, transconductance of the transistor MN7 and the capacitor C1 provide resistance and capacitance in the feedback circuit. As a result, an RC ring oscillator construction is obtained.

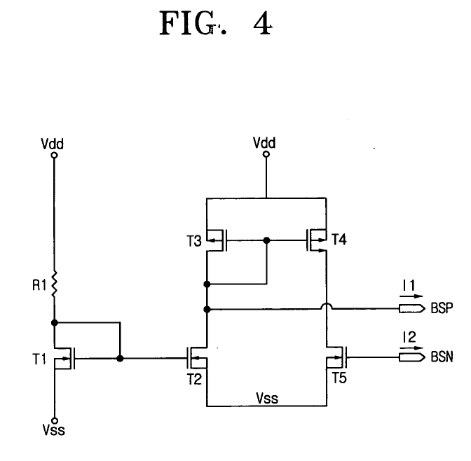

FIG. 4 is a circuit diagram of an example of the current mirror circuit of FIG. 3. Referring to FIG. 4, the current mirror circuit 111 includes a resistor R1 and a plurality of transistors T1 to T5. A current flowing from the bias power source Vdd to the resistor R1 is mirrored by the transistors T1 and T2 arranged to face each other. Thus, the current becomes a drain current of the transistor T3. Meanwhile, the drain current of the transistor T3 is mirrored by the transistor T4 arranged to face the transistor T3, so that the current flows along a drain terminal of the transistor T4. As a result, first and second currents I1 and I2 are output through terminals BSP and BSN respectively connected to the drain terminal of the transistor T3 and the gate of transistor T5.

Referring to the circuit of FIG. 3, the first and second currents I1 and I2 output from the current mirror circuit 111 respectively flow to the PMOS and NMOS transistors in the current limit circuit 112.

In this case, a current transfer characteristic ratio between the respective PMOS and NMOS transistors in the current limit circuit 112 may be 2:1. By doing so, gate threshold voltages of the transistors constituting the inverters 121 to 125 and 130 are maintained at Vdd/2, and the final output signal of the ultra low power oscillator has up-down symmetry around a center level.

The current transfer characteristic can be expressed by Equation (1).

$$I = \frac{μ * C}{2} * \frac{W}{L} * {( {v}_{gs} - {V}_{t} )}^{2} \qquad ( 1 )$$

In Equation (1), μ represents electron mobility in a MOS-channel, C represents capacitance per unit area of a flat capacitor formed by a gate electrode and a channel, W represents a width of the gate electrode, L represents a length of the gate electrode, V_{gs} represents a potential difference between gate and source, and Vₜ represents a threshold voltage, respectively. According to Equation (1), the output current, i.e., the current transfer characteristic, may be varied by the width and the length of the gate electrode and the voltage between the gate and the source. Therefore, the current limit circuit 112 is preferably, but not necessarily, provided by using a PMOS transistor having a gate width twice the size of an NMOS transistor. By doing so, the first low current is twice the amount of the second low current.

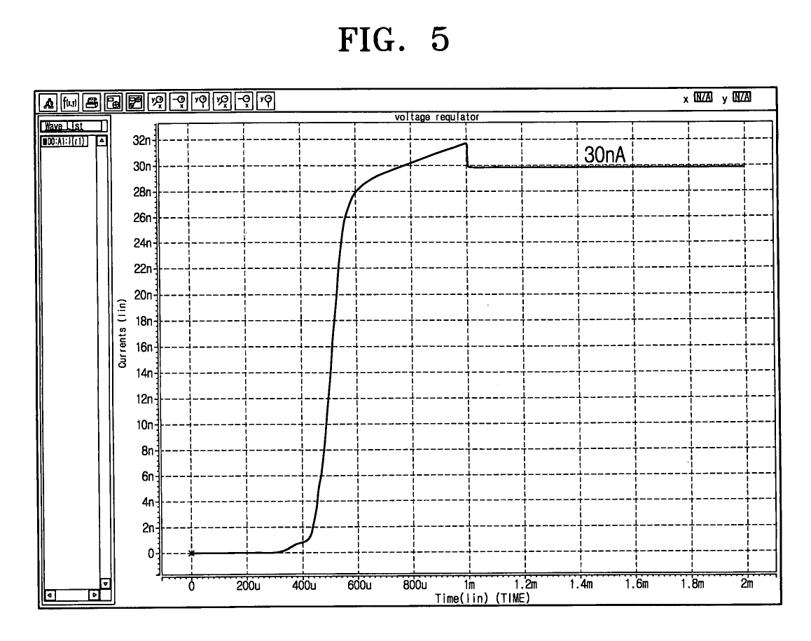

FIGS. 5 to 7 are graphs illustrating experimental simulation results of the ultra low power oscillator according to the present invention.

Specifically, FIG. 5 is a graph illustrating the waveform of the low current supplied through the current limit circuit 112. Referring to FIG. 5, the current supplied to the oscillation unit 120 is substantially 30 nA. Therefore, power consumption is not increased even if the NMOS and PMOS transistors in each inverter are simultaneously turned on during switching of the external control signal.

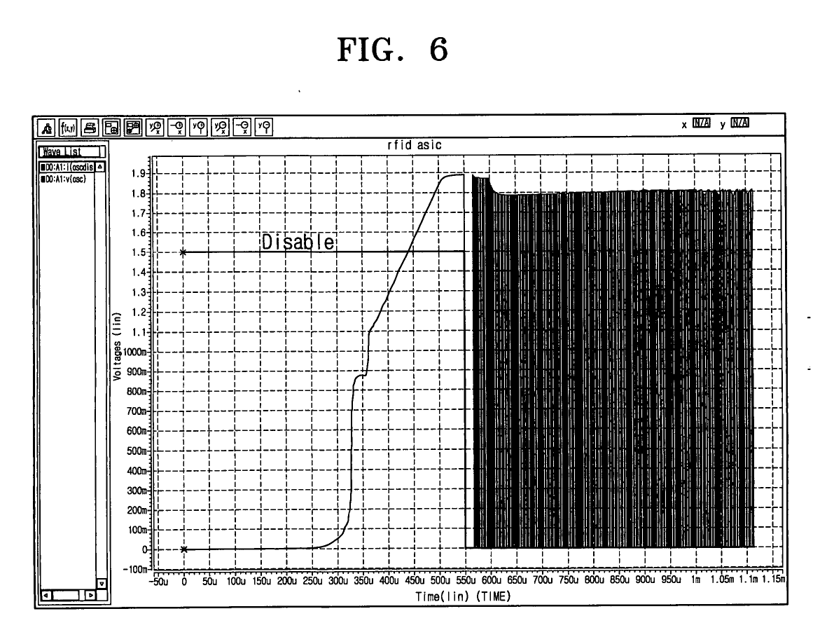

FIG. 6 is a graph illustrating the output waveform of the ultra low power oscillator according to the present invention. Referring to FIG. 6, it is noted that oscillation does not occur in a disable period where the transistor switch MN14 connected with the feedback circuit is turned on, and occurs as soon as the transistor switch MN14 is turned off (substantially, after 570 μS).

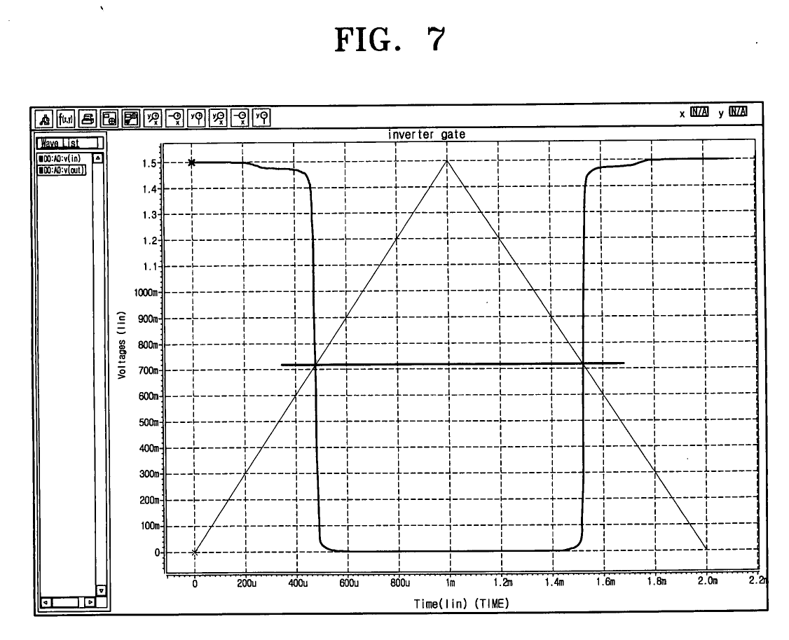

FIG. 7 is a graph illustrating the output waveform of the ultra low power oscillator according to the present invention. Referring to FIG. 7, the output waveform is symmetric about the center level as the respective current transfer characteristics of the PMOS and NMOS transistors in the current limit circuit are set at a ratio of 2:1.

As described above, in the present invention, the current supplied to each inverter is limited using the current limit circuit to reduce power consumption, so that the ultra low power oscillator can be implemented. Also, in the present invention, the output signal of the ultra low power oscillator has a symmetric waveform about the center level, and thus it is possible to avoid a signal loss.

The foregoing embodiments and advantages are merely exemplary and are not to be construed as limiting the present invention. The present teaching can be readily applied to other types of apparatuses. Also, the description of the exemplary embodiments of the present invention is intended to be illustrative, and not to limit the scope of the claims, and many alternatives, modifications, and variations will be apparent to those skilled in the art.

What is claimed is:

1. An ultra low power oscillator comprising:
a current supply unit which converts current supplied from an external bias power source into first and second low currents of predetermined amounts; and
an oscillation unit which oscillates and creates a predetermined frequency signal if the first and second low currents are supplied from the current supply unit.

2. The ultra low power oscillator as claimed in claim 1, wherein the oscillation unit comprises a plurality of inverters connected in series.

3. The ultra low power oscillator as claimed in claim 2, wherein the oscillation unit is constructed in the form of a ring including output and input terminals connected to each other by a feedback circuit.

4. The ultra low power oscillator as claimed in claim 3, wherein the oscillation unit further comprises a transistor switch that is connected to the feedback circuit to control oscillation.

5. The ultra low power oscillator as claimed in claim 3, further comprising an output buffering unit which buffers output signals of the oscillation unit and outputs the buffered output signals.

6. The ultra low power oscillator as claimed in claim 3, wherein the inverter comprises:
a first PMOS transistor including a source terminal to which the first low current is applied; and
a first NMOS transistor including a source terminal to which the second low current is applied.

7. The ultra low power oscillator as claimed in claim 6, wherein the current supply unit comprises:
a current mirror circuit which detects first and second currents from the bias power source; and
a current limit circuit which converts the first and second currents into the first and second low currents and supplies the converted currents to the oscillation unit.

8. The ultra low power oscillator as claimed in claim 7, wherein the current limit circuit comprises:
a second PMOS transistor including a drain terminal connected to the source terminal of the first PMOS transistor; and
a second NMOS transistor including a drain terminal connected to the source terminal of the first NMOS transistor.

9. The ultra low power oscillator as claimed in claim 8, wherein the second PMOS transistor has a current transfer characteristic twice that of the second NMOS transistor.
